(19) United States
(12) Patent Application Publication
(10) Pub. No.: US 2020/0356744 A1
(43) Pub. Date: Nov. 12, 2020

(54) SENSOR, MANUFACTURING METHOD THEREOF, PANEL AND RECOGNITION DEVICE

(71) Applicant: BOE TECHNOLOGY GROUP CO., LTD., Beijing (CN)

(72) Inventor: Qiang WANG, Beijing (CN)

(21) Appl. No.: 16/482,008

(22) PCT Filed: Jan. 10, 2019
(86) PCT No.: PCT/CN2019/071079

§ 371 Date: Jul. 30, 2019

(30) Foreign Application Priority Data
May 4, 2018 (CN) 201810421486.4

(51) Int. Cl. G06K 9/00; H01L 41/08; H01L 41/047

(52) U.S. Cl. CPC G06K 9/0002; H01L 41/047; H01L 41/0805

(57) ABSTRACT

A sensor, a manufacturing method thereof, a panel, and a recognition device are provided. The sensor comprises a substrate, a first electrode layer on the substrate, a second electrode layer on a side of the first electrode layer away from the substrate, and a piezoelectric layer between the first electrode layer and the second electrode layer. An orthographic projection of a top surface of the piezoelectric layer facing away from the first electrode layer on the substrate covers an orthographic projection of a bottom surface thereof facing the first electrode layer on the substrate.

### RELATED APPLICATION

The present application claims the benefit of Chinese Patent Application No. 201810421486.4, filed on May 4, 2018, the entire disclosure of which is incorporated herein by reference.

### TECHNICAL FIELD

The present disclosure relates to electronic technologies, and especially to a sensor, a manufacturing method thereof, a panel and a recognition device.

### BACKGROUND

Biometric technology is an important development direction for display panels and display modules. Currently, common implementation method for biometrics includes capacitive sensing, optical detection, pressure sensing, temperature sensing, ultrasonic detection, etc. The ultrasonic detection method has received more and more attention due to its advantages such as being contactless, being unobstructed, having high precision, and the like.

### SUMMARY

An embodiment of the present disclosure provides a sensor. The sensor comprises: a substrate, a first electrode layer on the substrate, a second electrode layer on a side of the first electrode layer away from the substrate, and a piezoelectric layer between the first electrode layer and the second electrode layer. An orthographic projection of a top surface of the piezoelectric layer facing away from the first electrode layer on the substrate covers an orthographic projection of a bottom surface of the piezoelectric layer facing the first electrode layer on the substrate.

In some embodiments, the orthographic projection of the top surface of the piezoelectric layer on the substrate is circular or square.

In some embodiments, a section of the piezoelectric layer along a direction perpendicular to a plane of the substrate is in an inverted trapezoidal shape.

In some embodiments, the first electrode layer is in direct contact with the substrate.

In some embodiments, the sensor further comprises a pad layer between the first electrode layer and the second electrode layer, the pad layer is located around the piezoelectric layer and comprises at least one groove filled with a medium.

In some embodiments, the medium filled in the groove has an acoustic impedance greater than an acoustic impedance of the pad layer.

In some embodiments, the medium comprises air, silicon nitride or silicon dioxide.

In some embodiments, a section of the groove along a direction perpendicular to the substrate is perpendicular to the first electrode layer.

In some embodiments, at least some of the at least one groove surround the piezoelectric layer.

In some embodiments, each of the at least one groove surrounds the piezoelectric layer.

In some embodiments, a depth of the at least one groove in a direction perpendicular to the substrate is equal to a thickness of the pad layer.

In some embodiments, the sensor is configured to perform ultrasonic biometric recognition.

Another embodiment of the disclosure provides a panel comprising at least one sensor according to any one of the foregoing embodiments.

Another embodiment of the disclosure provides a recognition device comprising the panel according to the above embodiment.

In some embodiments, the recognition device further comprises a control module, a signal acquisition module and a recognition module. The control module is configured to apply a first electrical signal to the sensor. The sensor is configured to generate and transmit an ultrasonic signal in response to receiving the first electrical signal, and further configured to output a second electrical signal in response to receiving a reflected ultrasonic signal from an external object. The signal acquisition module is configured to acquire the second electrical signal outputted by the sensor, and the recognition module is configured to process the second electrical signal to recognize the external object.

Yet another embodiment of the disclosure provides a method for manufacturing a sensor, comprising: providing a substrate; forming a first electrode layer on the substrate; forming a piezoelectric layer on the first electrode layer, an orthographic projection of a top surface of the piezoelectric layer facing away from the first electrode layer on the substrate covering an orthographic projection of a bottom surface of the piezoelectric layer facing the first electrode layer on the substrate, and forming a second electrode layer on the piezoelectric layer.

In some embodiments, forming a piezoelectric layer on the first electrode layer comprises: forming a pad layer on the first electrode layer; performing a patterning process to the pad layer to form an opening to expose the first electrode layer, and filling a piezoelectric material in the opening to form the piezoelectric layer. The method further comprises forming at least one groove independent of the opening in the pad layer.

### BRIEF DESCRIPTION OF THE DRAWINGS

The accompanying drawings intend to provide a further understanding of the technical solutions set forth in embodiments of the disclosure, and constitute a part of the specification, which are used together with the literal description of the present application to illustrate the embodiments of the disclosure, without limiting the scope of the present application.

FIG. 1 is a schematic view of an ultrasonic fingerprint recognition device known by inventors of the present application;

FIG. 2 is a schematic view of a sensor provided by an embodiment of the present disclosure;

FIG. 3a is a schematic view of a sensor provided by another embodiment of the present disclosure;

FIG. 3b is a schematic view of a sensor provided by a further embodiment of the present disclosure;

FIG. 4 is a transverse sectional view of a sensor provided by an embodiment of the present disclosure;

FIG. 5 intends to illustrate propagation paths of ultrasonic waves within a sensor provided by an embodiment of the present disclosure;

FIG. 6 illustrates transmission and reflection of ultrasonic waves during a fingerprint recognition process provided by an embodiment of the present disclosure;

FIG. 7 is a schematic view of a panel provided by an embodiment of the present disclosure;

FIG. 8 is a schematic view of a recognition device provided by an embodiment of the present disclosure;

FIG. 9 is a flowchart of a method for manufacturing a sensor provided by an embodiment of the present disclosure;

FIGS. 10a-10d are used to illustrate a sensor manufacturing process provided by an embodiment of the present disclosure.

### DETAILED DESCRIPTION OF EMBODIMENTS

In order to make the purpose, technical solutions and advantages of the present disclosure more clear and explicit, embodiments of the disclosure will be described in detail below with reference to the accompanying drawings. It is to be noted that, embodiments in the disclosure and features in the embodiments may be combined in any manner to obtain different embodiments in the case of causing no conflict, and these embodiments also fall within the protection scope of the present application.

Unless otherwise defined, technical terms or scientific terms used herein should have common meanings understood by a person of ordinary skill in the field to which the present disclosure pertains. The words such as “first”, “second”, and the like used in the present disclosure do not denote any order, quantity, or importance, but are used to distinguish different components. The word such as “comprising”, “including” or the like mean that an element or item preceding the word encompasses elements or items and equivalents thereof listed after that word, but do not exclude other elements or items. The words such as “connect”, “link” and the like are not limited to physical or mechanical connections, but may include electrical connections, regardless of being direct or indirect. “Upper”, “lower”, “left”, “right”, or the like is only used to indicate a relative positional relationship, and when the absolute position of the described object is changed, the relative positional relationship may also change accordingly.

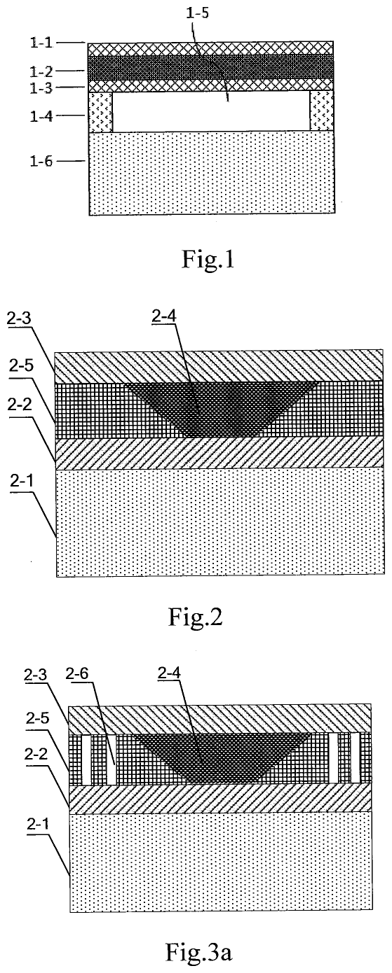

Inventors of the present application have realized that ultrasonic fingerprint recognition devices in the related art generally involve a microelectromechanical system (MEMS) that requires a cantilever beam structure, which are difficult to fabricate, low in yield and short in lifetime, and are not applicable to flexible display. For example, as shown in FIG. 1, an ultrasonic fingerprint recognition device known to inventors comprises an upper electrode 1-1, a piezoelectric material 1-2, a lower electrode 1-3, a spacer 1-4, an air layer 1-5 and a substrate 1-6.

FIG. 2 is a longitudinal sectional view of a sensor provided by an embodiment of the present disclosure. As shown in FIG. 2, a sensor provided by an embodiment of the disclosure comprises a substrate 2-1, a first electrode layer 2-2 on the substrate 2-1, a second electrode layer 2-3 on a side of the first electrode layer 2-2 away from the substrate, and a piezoelectric layer 2-4 between the first electrode layer 2-2 and the second electrode layer 2-3. An orthographic projection of the top surface of the piezoelectric layer 2-4 facing away from the first electrode layer 2-2 on the substrate 2-1 covers that of the bottom surface of the piezoelectric layer 2-4 facing the first electrode layer 2-2 on the substrate 2-1. That is, the end face of the piezoelectric layer 2-4 close to the substrate 2-1 is smaller, and the end face of the piezoelectric layer 2-4 away from the substrate 2-1 is larger, forming a cup-shaped structure, which may be referred to herein as a reflective cup. In some embodiments, the piezoelectric layer 2-4 may be in direct contact with the first electrode layer 2-2 and the second electrode layer 2-3, respectively. In other embodiments, any appropriate intermediate layer may be present between the piezoelectric layer 2-4 and the first electrode layer 2-2 or the second electrode layer 2-3.

For the sensor provided by this embodiment, the substantially cup-shaped piezoelectric layer can restrict the propagation directions of ultrasonic waves. The ultrasonic waves would be reflected multiple times within the piezoelectric layer, so that the ultrasonic waves propagate intensively towards the upper side (the end having a larger surface area) of the reflective cup, and ultrasonic signals at the upper side of the reflective cup can be enhanced to improve the detection capability of the sensor. This will be further explained below.

It is to be noted that the sectional shape of the piezoelectric layer 2-4 in FIG. 2 along a plane perpendicular to the substrate is only an example, and the present application is not limited thereto. For example, the section of the piezoelectric layer 2-4 in FIG. 2 is of an inverted trapezoidal shape, but in other embodiments, the upper and lower edges of the inverted trapezoidal shape are not connected by straight lines, but are connected by curves.

According to some embodiments of the present disclosure, the first electrode layer 2-2 and the second electrode layer 2-3 are made of ITO (indium tin oxide), silver nanowires or the like.

The piezoelectric layer 2-4 is made of a piezoelectric material such as PVDF (polyvinylidene fluoride). Of course, the present application is not limited thereto, and other types of piezoelectric materials may be utilized. The piezoelectric layer 2-4 is configured to achieve conversion between an electrical signal and an ultrasonic signal. Specifically, in case an electrical signal is applied between the first electrode layer 2-2 and the second electrode layer 2-3, the piezoelectric layer converts the electrical signal into an ultrasonic signal. When the ultrasonic signal is reflected back into the piezoelectric layer, the piezoelectric layer converts it into an electrical signal.

According to an embodiment of the present disclosure, as shown in FIG. 2, the sensor further comprises a pad layer 2-5, and the pad layer 2-5 is disposed between the first electrode layer 2-2 and the second electrode layer 2-3 and outside the piezoelectric layer 2-4. For example, the material forming the pad layer 2-5 includes, but is not limited to, an oxide of silicon, a nitride of silicon, a photoresist, or the like.

In some embodiments, the first electrode layer 2-2 is disposed on a surface of the substrate 2-1. That is, the first electrode layer 2-2 is in direct contact with the substrate 2-1. That is, in this embodiment, the sensor may not require a cantilever beam structure, so that the manufacturing difficulty is decreased, the yield and the service life of the sensor are increased, and the sensor is applicable to flexible display. In other embodiments, other layers such as a cantilever beam structure may also be present between the first electrode layer 2-2 and the substrate 2-1.

In the embodiment of FIG. 2, the piezoelectric layer 2-4 is at the center of the surface of the first electrode layer 2-2. Of course, the present application is not limited thereto, and the piezoelectric layer may deviate from the center of the surface of the first electrode layer 2-2.

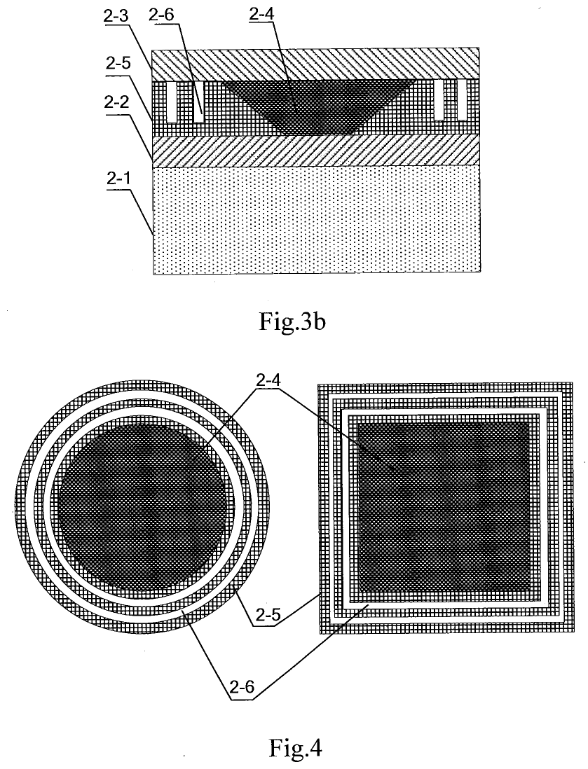

As shown in FIG. 3a, a sensor provided by another embodiment of the present disclosure differs from the sensor shown in FIG. 2 in that the pad layer 2-5 is provided with at least one groove 2-6 filled with a medium.

In some embodiments, the acoustic impedance of the medium filled in the groove 2-6 is greater than that of the pad layer. The structure formed by the groove is hereinafter referred to as an acoustic barrier structure. In this embodiment, the high acoustic impedance reflection characteristic at the interface between the pad layer 2-5 and the groove 2-6 is utilized to greatly reduce the propagation and diffusion of the ultrasonic wave in the lateral direction, and further enhance the propagation of the ultrasonic signal towards the upper side of the piezoelectric layer 2-4, thereby reducing attenuation of the ultrasonic signal propagation and improving the detection capability of the sensor.

According to an embodiment of the disclosure, the medium filled in the groove includes air. Of course, it may be other materials such as silicon nitride (SiNₓ), silicon dioxide (SiO₂), and the like.

In the example of FIG. 3a, a section of the groove 2-6 along a vertical plane perpendicular to the substrate is perpendicular to the first electrode layer 2-2. In this way, it is advantageous for promoting the reflection of the ultrasonic wave by the acoustic barrier structure, and further reducing the propagation of the ultrasonic signal in the lateral direction. The term “vertical” or other terms denoting directions as referred to herein are based on the orientation of the sensor as shown in the drawings and do not represent absolute directions.

In the example of FIG. 3a, the groove 2-6 penetrates through the pad layer 2-5, and the depth of the groove in the vertical direction is equal to the thickness of the pad layer (i.e., the groove 2-6 penetrates through the entire pad layer 2-5 in the vertical direction). Alternatively, in other embodiments, as shown in FIG. 3b, the groove 2-6 may also be a non-penetrating groove (i.e., the groove 2-6 does not penetrate through the pad layer 2-5). In embodiments where a plurality of grooves are present, part of the grooves may penetrate through the pad layer 2-5 while some other grooves may not penetrate through the pad layer 2-5.

Further, in case the pad layer 2-5 is provided with a plurality of grooves, the plurality of grooves may be equidistantly distributed. Of course, they may also be non-equidistantly distributed. The size of the groove 2-6 may be set as needed.

According to some embodiments of the disclosure, each of the grooves 2-6 may be disposed around the piezoelectric layer 2-4, for example, in the embodiment shown in FIG. 4. In another embodiment, the grooves 2-6 may be not completely around the piezoelectric layer 2-4, that is, the grooves 2-6 partially surrounds the piezoelectric layer 2-4. Alternatively, only some grooves surround the piezoelectric layer 2-4, and the other grooves do not completely surround the piezoelectric layer 2-4.

FIG. 4 is a transverse sectional view of a sensor provided by an embodiment of the present disclosure. As shown in FIG. 4, an orthographic projection of the piezoelectric layer 2-4 on the substrate is circular or square, that is, the cross section of the piezoelectric layer 2-4 along the plane of the substrate is circular or square. It is to be noted that, what are shown in FIG. 4 are just examples, and the orthographic projection of the piezoelectric layer 2-4 on the substrate may also have other shapes, such as a rectangle and the like. In addition, it can be seen that the grooves 2-6 surround the piezoelectric layer 2-4, so that the ultrasonic waves generated from the piezoelectric layer 2-4 can be reflected back to the piezoelectric layer 2-4 to the greatest extent, reducing loss of the ultrasonic wave. In this embodiment, the piezoelectric layer 2-4 may be a cylindrical structure having a smaller bottom and a larger top, or a cylindrical structure having a smaller bottom and a larger top.

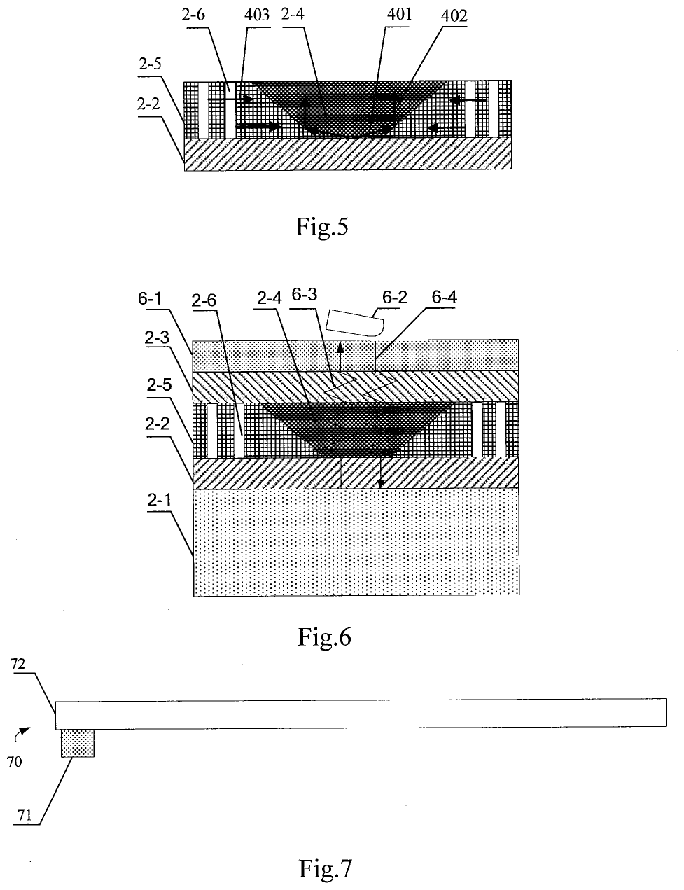

The reflection process of the ultrasonic waves in the sensor as shown in FIG. 3a will be discussed below with reference to FIG. 5. As shown in FIG. 5, the ultrasonic waves propagate towards the top of the reflective cup along the directions of an arrow 401 and an arrow 402, and the ultrasonic signals are concentrated and enhanced. Specifically, the cup-shaped piezoelectric layer restricts the propagation directions of the ultrasonic waves to a certain extent, and the ultrasonic waves finally propagate towards the top of the reflective cup after being reflected multiple times, so that the ultrasonic energy towards the top of the reflective cup is enhanced, thereby reducing energy attenuation of the ultrasonic waves during propagation. Further, as indicated by an arrow 403, when the ultrasonic wave in the lateral direction reaches the interface between the groove and the pad layer, it is reflected back to the reflective cup, so that loss of the ultrasonic wave in the lateral direction is reduced. That is, by utilizing the high acoustic impedance reflection characteristic at the interface between the medium and the air, the acoustic barrier structure greatly reduces the propagation and diffusion of the ultrasonic wave in the lateral direction, and further increases the energy of the ultrasonic signal propagating towards the upper side of the reflective cup, which is advantageous for improving the detection capability of the sensor.

The process of implementing fingerprint recognition using the sensor provided by embodiments of the present disclosure will be described below with reference to FIG. 6. As shown in FIG. 6, a display screen 6-1 is disposed on the second electrode layer 2-3, and a finger 6-2 is placed on a fingerprint scanning area of the display screen 6-1. When the fingerprint scanning function is enabled, an alternating current signal is applied between the first, electrode layer 2-2 and the second electrode layer 2-3, and an ultrasonic signal 6-3 can be generated based on the alternating current signal due to the inverse piezoelectric effect of the piezoelectric material. Being influenced by the reflective cup and the acoustic barrier structure, most of the ultrasonic signals 6-3 propagate along the reflective cup towards the upper side thereof and pass through the display screen 6-1 to reach the finger 6-2. Upon encountering the finger 6-2, the ultrasonic signal is reflected to generate a reflected signal 6-4 (which is also an ultrasonic signal), and the reflected signal 6-4 eventually returns to the piezoelectric layer 2-4. Due to the positive piezoelectric effect of the piezoelectric material, the piezoelectric layer generates charges on its surface in response to the reflected signal 6-4 to thereby generate an electrical signal between the first electrode layer 2-2 and the second electrode layer 2-3. It can be understood that the ultrasonic signals reflected back from different positions (e.g., the valleys and the ridges) of the finger 6-2 would have different intensities, so that electrical signals generated between the first electrode layer 2-2 and the second electrode layer 2-3 would also be different in intensity, hence, the fingerprint recognition function can be realized by acquiring, processing and discriminating the electrical signals. Likewise, the sensors proposed by the embodiments of the present disclosure can also perform recognition to palm print, skin and other biological signs.

As shown in FIG. 7, another embodiment of the present disclosure provides a panel 70 comprising a sensor 71 described in any of the foregoing embodiments. In the example of FIG. 7, the panel 70 comprises a display screen 72 disposed on a side of the second electrode layer 2-3 away from the substrate. The display screen 72 can provide a touch surface for a user to touch. The ultrasonic signal generated by the sensor 71 can pass through the display screen 72 to reach the finger, and the ultrasonic signal reflected by the finger passes through the display screen 72 to reach the sensor 71, the sensor 71 would convert the reflected ultrasonic signal into an electrical signal. The sensor 71 is disposed in a non-display area of the panel 70.

In another embodiment, the panel comprises a sensor array consisting of a plurality of sensors. The panel may be a liquid crystal display panel, an organic light emitting diode panel, and the like.

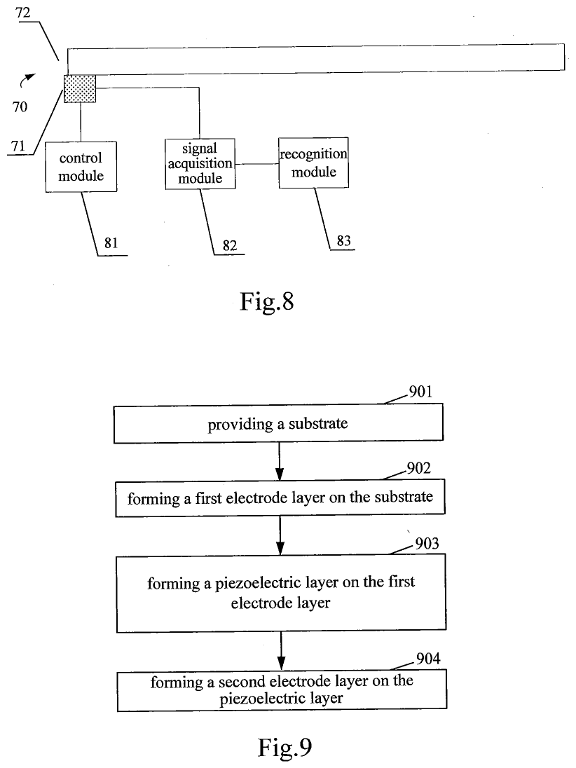

As shown in FIG. 8, a further embodiment of the present disclosure provides a recognition device comprising the panel 70 described in the above embodiment. The recognition device further comprises a control module 81, a signal acquisition module 82, and a recognition module 83. The control module 81 is configured to apply a first electrical signal to the sensor 71, and the sensor 71 is configured to generate an ultrasonic signal and transmit the ultrasonic signal in response to receiving the first electrical signal. The ultrasonic signal may be reflected back to the recognition device upon encountering an external object, and the sensor is further configured to output a second electrical signal in response to receiving the ultrasonic signal reflected back by the external object. The signal acquisition module 82 is configured to acquire the second electrical signal outputted by the sensor 71. The recognition module 83 is configured to process the second electrical signal to generate image information for recognizing the external object. The control module mentioned herein may comprise a voltage generator that may generate the first electrical signal based on a supply voltage received by the recognition device. The acquisition module may comprise an A/D conversion circuit, an operational amplification circuit, a D/A conversion circuit, and a voltage stabilization and filtering circuit. A known image recognition algorithm may be integrated in the recognition module to generate a recognition image based on the received second electrical signal. In some embodiments, the functionality of the recognition module can be implemented in pure software, in which case the recognition module comprises program codes for executing the known image recognition algorithm mentioned above. According to an embodiment of the present disclosure, an image for recognizing an external object is, for example, a fingerprint image, a palm print pattern, or the like, thereby achieving biometric recognition such as fingerprint recognition, palm print recognition, and the like. Of course, the present disclosure is not limited to biometric recognition, but is also applicable to other texture recognition. The recognition device may be an independent detection device, or may be integrated in an apparatus such as a terminal, a tablet, an access control system, or the like.

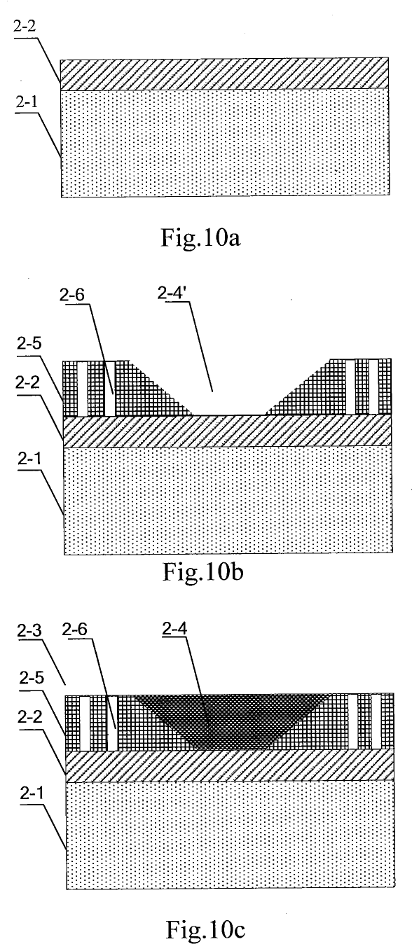

As shown in FIG. 9, yet another embodiment of the present disclosure provides a method for manufacturing a sensor comprising the following steps: step 901, providing a substrate; step 902, forming a first electrode layer on the substrate; step 903, forming a piezoelectric layer on the first electrode layer, the orthographic projection of the top surface of the piezoelectric layer facing away from the first electrode layer on the substrate covering that of the bottom surface of the piezoelectric layer facing the first electrode layer on the substrate; step 904, forming a second electrode layer on the piezoelectric layer.

According to some embodiments of the disclosure, forming a piezoelectric layer on the first electrode layer comprises: forming a pad layer on the first electrode layer, performing a patterning process to the pad layer to form an opening to expose the first electrode layer, and filling a piezoelectric material in the opening to form the piezoelectric layer. According to another embodiment of the disclosure, the method further comprises forming at least one groove independent of the opening in the pad layer.

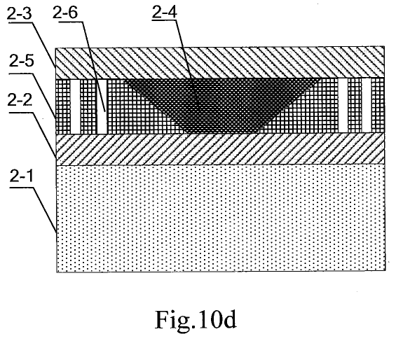

FIGS. 10a-10d illustrate a sensor manufacturing process provided by an embodiment of the present disclosure. Referring to FIGS. 10a-10d, the sensor manufacturing method provided by this embodiment comprises the following process.

As shown in FIG. 10a, a first electrode layer 2-2 is formed on a substrate 2-1 by a patterning process such as sputtering, deposition, photolithography, or the like. The first electrode layer 2-2 may be an electrode matrix. The substrate 2-1 may be a glass substrate. The material of the first electrode layer 2-2 may comprise ITO or silver nanowires, or the like.

In this embodiment, the patterning process is, for example, a photolithographic patterning process including, for example, coating a photoresist layer on a structure layer to be patterned, exposing the photoresist layer using a mask plate, developing the exposed photoresist layer to obtain a photoresist pattern, etching the structure layer by means of the photoresist pattern, and then removing the photoresist pattern. In other embodiments, the patterning process may be screen printing, an is inkjet printing method, and the like.

As shown in FIG. 10b, a pad layer material is deposited on the first electrode layer 2-2 to form a pad layer 2-5, and the pad layer 2-5 is patterned to form a groove 2-6 and a reflective cup region 2-4′. The pad layer 2-5 material includes SiNₓ, silicon oxide (SiOₓ), aluminum oxide (Al₂O₃), aluminum nitride (AlN), or other suitable materials. In an embodiment, exposed patterns of the reflective cup region 2-4′ and the groove 2-6 can be accomplished at one time by utilizing a half-tone mask.

As shown in FIG. 10c, a piezoelectric material is spin-coated in the reflective cup region 2-4′ by a spin-coating apparatus to form a piezoelectric layer 2-4. After the piezoelectric material is filled, it may be subjected to manufacturing processes such as solidification, crystallization, polarization, and the like. Examples of the piezoelectric material include, but are not limited to, PVDF. As shown in FIG. 10d, a second electrode layer 2-3 is formed on the pad layer 2-5 by a patterning process such as sputtering, photolithography, or the like. As a result, the sensor shown in FIG. 3a can be obtained.

It can be understood that the drawings for embodiments of the disclosure relate only to the structures or components described in the embodiments, and other necessary structures and components in the sensor, panel or recognition device may be referred to the general design. For the sake of clarity, in the drawings for describing embodiments of the present disclosure, the thickness of layer or region is enlarged or reduced, that is, the drawings are not necessarily drawn to scale. It can be understood that when an element such as a layer, a film, a region or a substrate is referred to as being located “above” or “below” another element, that element may be “directly” located “above” or “below” the another element, or intermediate elements may be present. Further, in the case of causing no conflict, embodiments of the present disclosure and the features in the embodiments may be combined with each other to obtain new embodiments, which are obvious variations of the embodiments described herein. Moreover, steps illustrated in the flowchart in the drawings may be executed in a computer system such as a set of computer executable instructions. Although a logical order is shown in the flowchart, in some cases, the steps shown or described may be performed in an order different from the one illustrated herein.

Some embodiments of the disclosure have been described above, but the description is only intended to facilitate understanding of the disclosure, rather than to limit the scope of the present application. A person skilled in the art can make any modifications and changes to the forms and details of the disclosed embodiments without departing from the spirit and scope revealed by the disclosure, and these modifications and changes all fall within the scope of the present application.

1. A sensor comprising:
a substrate,
a first electrode layer on the substrate,
a second electrode layer on a side of the first electrode layer away from the substrate, and
a piezoelectric layer between the first electrode layer and the second electrode layer,
wherein an orthographic projection of a top surface of the piezoelectric layer facing away from the first electrode layer on the substrate covers an orthographic projection of a bottom surface of the piezoelectric layer facing the first electrode layer on the substrate.

2. The sensor according to claim 1, wherein the orthographic projection of the top surface of the piezoelectric layer on the substrate is circular or square.

3. The sensor according to claim 1, wherein a section of the piezoelectric layer along a direction perpendicular to a plane of the substrate is in an inverted trapezoidal shape.

4. The sensor according to claim 1, wherein the first electrode layer is in direct contact with the substrate.

5. The sensor according to claim 1,
wherein the sensor further comprises a pad layer between the first electrode layer and the second electrode layer,
wherein the pad layer is around the piezoelectric layer and comprises at least one groove filled with a medium.

6. The sensor according to claim 5, wherein the medium filled in the groove has a first acoustic impedance greater than a second acoustic impedance of the pad layer.

7. The sensor according to claim 5, wherein the medium comprises air, silicon nitride or silicon dioxide.

8. The sensor according to claim 5, wherein a section of the groove along a direction perpendicular to the substrate is perpendicular to the first electrode layer.

9. The sensor according to claim 5, wherein at least some of the at least one groove surround the piezoelectric layer.

10. The sensor according to claim 9, wherein each of the at least one groove surrounds the piezoelectric layer.

11. The sensor according to claim 8, wherein a depth of the at least one groove in the direction perpendicular to the substrate is equal to a thickness of the pad layer.

12. The sensor according to claim 5, wherein the sensor is configured to perform ultrasonic biometric recognition.

13. A panel comprising at least one sensor according claim 1.

14. A recognition device comprising the panel according to claim 13.

15. The recognition device according to claim 14, wherein the recognition device further comprises a controller, a signal detector and a recognition module,
wherein the controller is configured to apply a first electrical signal to the sensor,
wherein the sensor is configured to generate and transmit an ultrasonic signal in response to receiving the first electrical signal, and further configured to output a second electrical signal in response to receiving a reflected ultrasonic signal from an external object,
wherein the signal detector is configured to acquire the second electrical signal output by the sensor, and
wherein the recognition module is configured to process the second electrical signal to recognize the external object.

16. A method for manufacturing a sensor, comprising:
providing a substrate;
forming a first electrode layer on the substrate;
forming a piezoelectric layer on the first electrode layer, wherein an orthographic projection of a top surface of the piezoelectric layer facing away from the first electrode layer on the substrate covers an orthographic projection of a bottom surface of the piezoelectric layer facing the first electrode layer on the substrate; and
forming a second electrode layer on the piezoelectric layer.

17. The method according to claim 16,
wherein forming the piezoelectric layer on the first electrode layer comprises forming a pad layer on the first electrode layer, performing a patterning process to the pad layer to form an opening to expose the first electrode layer, and filling a piezoelectric material in the opening to form the piezoelectric layer, and
wherein the method further comprises forming at least one groove independent of the opening in the pad layer.
